(19) United States
(12) Patent Application Publication
(10) Pub. No.: US 2008/0006940 A1
(43) Pub. Date: Jan. 10, 2008

(54) Lead frames, microelectronic devices with lead frames, and methods for manufacturing lead frames and microelectronic devices with lead frames

(75) Inventors: Wei Zhou, Singapore (SG); Bok Leng Ser, Singapore (SG)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/507,718

(22) Filed: Aug. 21, 2006

(30) Foreign Application Priority Data
Jul. 5, 2006 (SG) 200604534-8

(51) Int. Cl. H01L 23/48

(52) U.S. Cl. 257/737

(57) ABSTRACT

Lead frames, microelectronic devices with lead frames, and methods for manufacturing lead frames and microelectronic devices with lead frames are disclosed herein. An embodiment of one such microelectronic device includes a microelectronic die and a plurality of conductive leads connected to the die. The die includes an integrated circuit and a plurality of terminals operably coupled to the integrated circuit. The conductive leads are electrically coupled to corresponding terminals. The individual leads include a pad with a first side facing toward the die and a second side opposite the first side. The second side has a projection and/or a recess configured to interface with an interconnect element.

### CROSS-REFERENCE TO RELATED APPLICATION

This application claims foreign priority benefits of Singapore Application No. 200604534-8 filed Jul. 5, 2006.

### TECHNICAL FIELD

The present invention is related to lead frames, microelectronic devices with lead frames, and methods for manufacturing lead frames and microelectronic devices with lead frames.

### BACKGROUND

Microelectronic devices generally have a die (i.e., a chip) that includes integrated circuitry with a high density of very small components. In a typical process, a large number of dies are manufactured on a single wafer using many different processes that may be repeated at various stages (e.g., implanting, doping, photolithography, chemical vapor deposition, plasma vapor deposition, plating, planarizing, and etching). The dies typically include an array of very small bond-pads electrically coupled to the integrated circuitry. The bond-pads are external electrical contacts through which the supply voltage, signals, etc., are transmitted to and from the integrated circuitry. After forming the dies, the wafer is thinned by backgrinding, and then the dies are separated from one another (i.e., singulated) by dicing the wafer. Next, the dies are “packaged” to couple the bond-pads to a larger array of electrical terminals that can be more easily coupled to the various power supply lines, signal lines, and ground lines. Conventional processes for packaging dies include electrically coupling the bond-pads on the dies to an array of leads, ball-pads, or other types of electrical terminals, and then encapsulating the dies to protect them from environmental factors (e.g., moisture, particulates, static electricity, and physical impact).

Leaded packages, for example, include a die bonded to a lead frame with the die either seated on a die paddle or attached directly to the leads in a leads-over-chip arrangement. The bond-pads on the die are then wire-bonded to corresponding leads. The lead frame and die may then be encapsulated with a mold compound to form a packaged microelectronic device. In applications in which the leaded package includes a ball grid array, the casing encapsulating the lead frame includes openings at corresponding ball-pads on the leads. The openings are formed by contacting the ball-pads on the leads with corresponding projections in the mold during encapsulation. Next, a plurality of solder balls are placed in corresponding openings and attached to associated ball-pads. After connecting the solder balls, the packaged device can be attached to a printed circuit board or other external device.

One drawback of conventional methods for packaging a leaded device is that the projections in the mold may not contact the ball-pads and/or the mold compound may leak between the projections and the ball-pads. Accordingly, the encapsulated device may include mold flash over part or all of the individual ball-pads. It is difficult to remove the mold flash from the ball-pads without damaging the casing of the device. As a result, some conventional packaged leaded devices have mold flash between a portion of the solder ball and the ball-pad of one or more leads. In these devices, the mold flash may impair the structural and/or electrical connection between the solder ball and the ball-pad and render the devices defective.

One drawback of conventional packaged leaded devices is that the devices have a different coefficient of thermal expansion than the printed circuit boards to which they are attached. During operation, the difference in the coefficients of thermal expansion can create sufficient stress to cause failure in the solder ball connection between the printed circuit board and packaged device. Accordingly, there is a need to (a) improve conventional processes for packaging dies attached to lead frames, and (b) augment the robustness of the connection between the leaded devices and external members.

### BRIEF DESCRIPTION OF THE DRAWINGS

FIG. 1 is a schematic side cross-sectional view of a microelectronic device in accordance with one embodiment of the invention.

FIG. 2A is a top plan view of a section of one of the leads in FIG. 1 with the interconnect element and casing removed.

FIG. 2B is a schematic side cross-sectional view of the lead taken substantially along the line 2B-2B of FIG. 2A.

FIGS. 3-5 illustrate stages in one embodiment of a method for manufacturing the microelectronic device.

FIG. 3 is a schematic side cross-sectional view of the section of the lead illustrated in FIGS. 2A and 2B after forming the recess and depositing a sacrificial material into the recess.

FIG. 4 is a schematic side cross-sectional view of the section of the lead and the casing after removing the sacrificial material and the mold flash.

FIG. 5 is a schematic side cross-sectional view of the section of the lead and the casing after forming the interconnect element on the pad.

FIGS. 6-9 illustrate different configurations of recesses in pads of leads in accordance with other embodiments of the invention.

FIG. 10A is a top plan view of a section of a lead having a pad in accordance with another embodiment of the invention.

FIG. 10B is a schematic side cross-sectional view of the lead taken substantially along the line 10B-10B in FIG. 10A.

FIG. 11 is a schematic side cross-sectional view of a microelectronic device in accordance with another embodiment of the invention.

FIG. 12 is a schematic side cross-sectional view of a microelectronic device in accordance with another embodiment of the invention.

### DETAILED DESCRIPTION

### A. Overview

The following disclosure describes several embodiments of lead frames, microelectronic devices with lead frames, and methods for manufacturing lead frames and microelectronic devices with lead frames. An embodiment of one such microelectronic device includes a microelectronic die and a plurality of conductive leads connected to the die. The die has an integrated circuit and a plurality of terminals operably coupled to the integrated circuit. The conductive leads are electrically coupled to corresponding terminals on the die. The individual leads include a pad with a first side facing toward the die and a second side opposite the first side. The second side has a projection and/or a recess configured to interface with an interconnect element (e.g., solder ball).

In another embodiment, a microelectronic device includes a microelectronic die and a support member attached to the die. The die has an integrated circuit and a plurality of terminals operably coupled to the integrated circuit. The support member includes a plurality of pads electrically connected to corresponding terminals on the die. The individual pads include a first surface facing toward the die and a second surface opposite the first surface. The second surface has a first portion spaced apart from the first surface by a first distance and a second portion spaced apart from the first surface by a second distance different than the first distance.

Another aspect of the invention is directed to lead frames for carrying microelectronic dies. In one embodiment, a lead frame includes a plurality of leads. The individual leads have a mounting surface for attachment to a die and a contact site for coupling to an interconnect element. The individual contact sites include a connection feature and a first surface generally parallel to the mounting surface. The connection feature has a second surface transverse to the mounting surface.

Another aspect of the invention is directed to methods for manufacturing microelectronic devices. In one embodiment, a method includes mounting a microelectronic die to a support member, electrically connecting a plurality of terminals on the die to corresponding pads on the support member, encasing the die and a portion of the support member, and removing a sacrificial material from recesses in corresponding pads after encasing the die and the support member.

In another embodiment, a method includes mounting a microelectronic die to a lead frame having a plurality of leads. The individual leads include a pad with a first side facing toward the die and a second side opposite the first side. The second side has a projection and/or a recess positioned to interface with an interconnect element. The method further includes electrically coupling a plurality of terminals on the die to corresponding leads and encapsulating the die and a portion of the lead frame.

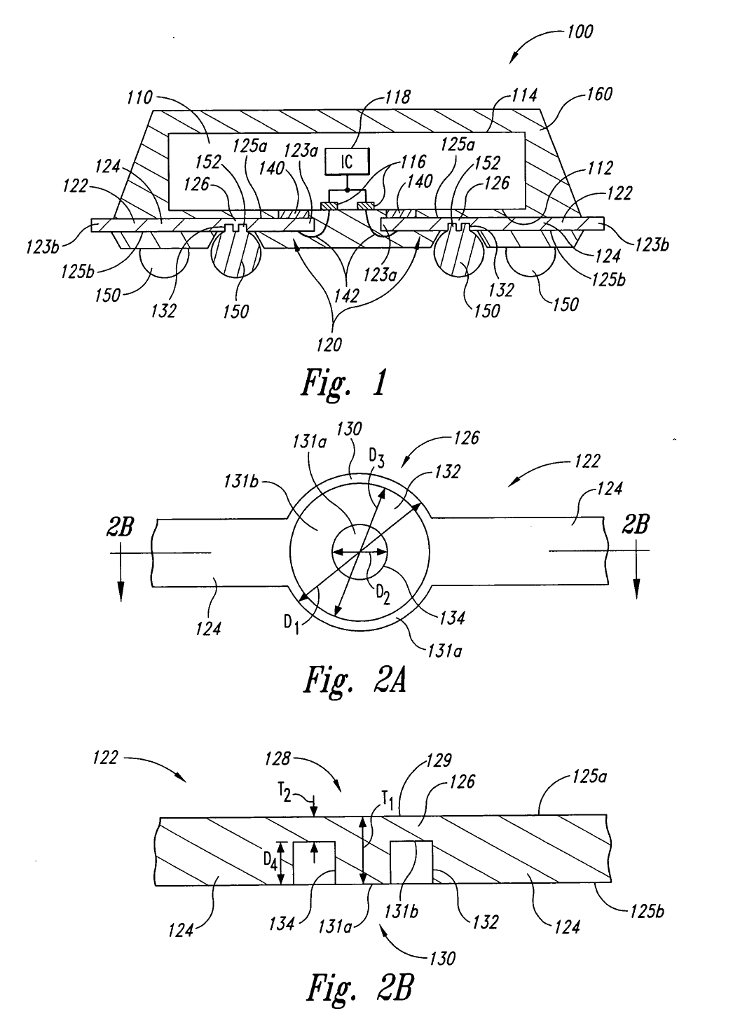

Specific details of several embodiments of the invention are described below with reference to microelectronic devices including microelectronic dies, but in other embodiments the microelectronic devices can include other components. For example, the microelectronic devices can include micromechanical components, data storage elements, optics, read/write components, or other features. Also, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 1-12.

### B. Embodiments of Microelectronic Devices

FIG. 1 is a schematic side cross-sectional view of a microelectronic device 100 in accordance with one embodiment of the invention. The illustrated microelectronic device 100 includes a microelectronic die 110, a support member or lead frame 120 mounted to the die 110, a plurality of interconnect elements 150 (e.g., solder balls) attached to the lead frame 120, and a casing 160 encapsulating the die 110 and a portion of the lead frame 120. The die 110 includes an active side 112, a back side 114 opposite the active side 112, a plurality of terminals 116 (e.g., bond-pads) arranged in an array on the active side 112, and an integrated circuit 118 (shown schematically) operably coupled to the terminals 116.

The lead frame 120 includes a plurality of leads 122 attached to the active side 112 of the die 110 with an adhesive 140. The individual leads 122 include an inner end 123a, an outer end 123b, and a body 124 extending between the inner and outer ends 123a-b. The inner ends 123a are electrically connected to corresponding terminals 116 on the die 110 with wire-bonds 142. The outer ends 123b may project from the casing 160 or be completely encapsulated by the casing 160. The individual bodies 124 include a first surface 125a facing toward the die 110, a second surface 125b opposite the first surface 125a, and a pad 126 to which a corresponding interconnect element 150 is attached. The illustrated individual pads 126 include a recess 132 for receiving a portion 152 of the corresponding interconnect element 150.

FIG. 2A is a top plan view of a section of one of the leads 122 with the interconnect element 150 and casing 160 removed. FIG. 2B is a schematic side cross-sectional view of the lead 122 taken substantially along the line 2B-2B of FIG. 2A. Referring to both FIGS. 2A and 2B, the pad 126 of the lead 122 has a first diameter D₁ (FIG. 2A), a first side 128 (FIG. 2B) facing toward the die 110 (FIG. 1), and a second side 130 opposite the first side 128. The first side 128 of the pad 126 has a first surface 129 that can be generally coplanar with the first surface 125a of the body 124. The second side 130 of the pad 126 includes the recess 132, a second surface 131a external to the recess 132 that can be generally coplanar with the second surface 125b of the body 124, and a third surface 131b within the recess 132.

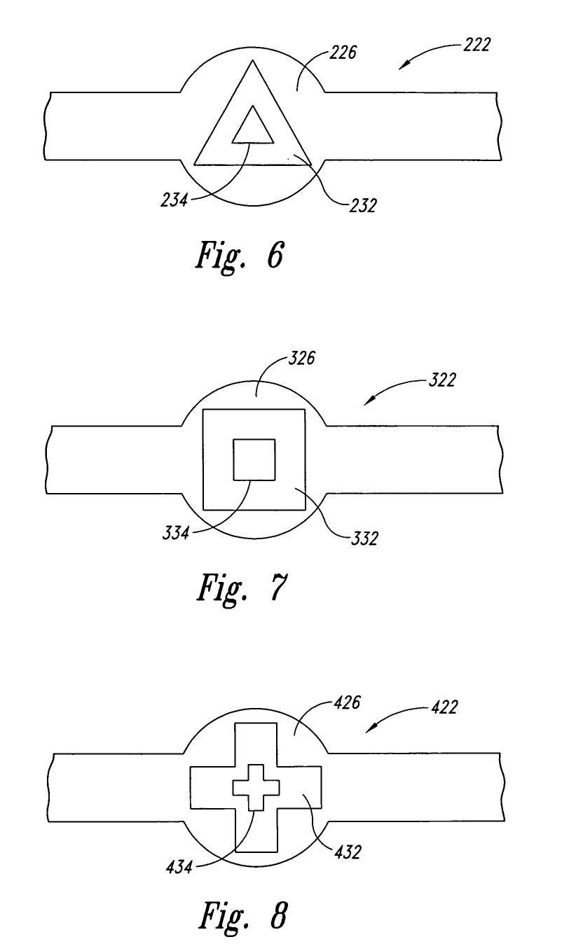

The illustrated recess 132 is an annular groove having an inner diameter D₂ and an outer diameter D₃. The outer diameter D₃ can be less than or equal to the first diameter D₁ of the pad 126. In one embodiment, the outer diameter D₃ can be approximately 400 μm, and the inner diameter D₂ can be approximately 150 μm. In other embodiments, the inner and/or outer diameters D₂ and/or D₃ can be different. In either case, the illustrated recess 132 defines a projection 134 at the center of the pad 126. The illustrated recess 132 is a blind groove that extends from the second surface 131a to an intermediate depth D₄ in the pad 126. As such, the pad 126 has a first thickness T₁ extending between the first surface 129 and the second surface 131a and a second, reduced thickness T₂ extending between the first surface 129 and the third surface 131b. In one application, the first thickness T₁ of the pad 126 can be approximately 125 μm, and the depth D₄ of the recess 132 can be approximately 100 μm. In other applications, however, the dimensions can be different. In additional embodiments, such as the embodiments described below with reference to FIGS. 6-9, the pad 126 can have a recess with a different configuration. Moreover, in other embodiments, such as the embodiment described below with reference to FIGS. 10A and 10B, the pad 126 may have a projection in lieu of or in addition to a recess.

One feature of the specific embodiment of the microelectronic device 100 illustrated in FIGS. 1-2B is that the portions 152 of the interconnect elements 150 are received in the recesses 132 of the pads 126 on the leads 122. An advantage of this feature is that the placement of the portions 152 of the interconnect elements 150 in the recesses 132 is expected to enhance the robustness of the connection between the leads 122 and the interconnect elements 150. Namely, the interface between the recesses 132 and the interconnect elements 150 is expected to provide a stronger connection or joint compared to leads without the recesses. For example, in one finite element simulation, a conventional connection between a solder ball and a flat pad on a lead had a maximum stress of 318 MPa, and the connection illustrated in FIGS. 1-2B had a maximum stress of 203 MPa. Thus, in the simulation, the illustrated connection reduced the maximum stress by approximately 36%. As a result, the illustrated microelectronic device 100 is expected to increase the reliability of the interconnect element connection between the device 100 and a printed circuit board or other external member.

### C. Embodiments of Methods for Manufacturing Microelectronic Devices

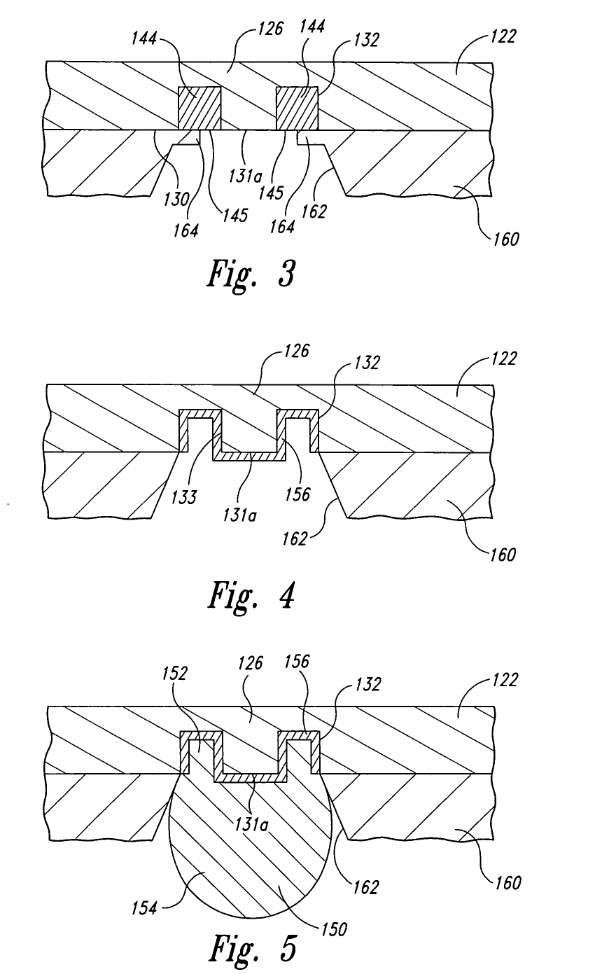

FIGS. 3-5 illustrate stages in one embodiment of a method for manufacturing the microelectronic device 100. For example, FIG. 3 is a schematic side cross-sectional view of the section of the lead 122 illustrated in FIGS. 2A and 2B after forming the recess 132 and depositing a sacrificial material 144 into the recess 132. The recess 132 can be formed by etching, stamping, or other suitable processes. The sacrificial material 144 can be deposited into the recess 132 by dispensing, printing, or other suitable processes. The illustrated sacrificial material 144 fills the recess 132 and includes an exposed surface 145 that is generally planar with the second surface 131 a of the pad 126. In other embodiments, however, the sacrificial material 144 may not completely fill the recess 132. In either case, after forming the recess 132 and depositing the sacrificial material 144, the lead frame 120 (FIG. 1) can be mounted to the die 110 (FIG. 1) and the assembly can be placed in a mold cavity to form the casing 160. As described above, conventional molding processes often produce mold flash 164 at an opening 162 aligned with the pad 126 of the lead 122. In the illustrated embodiment, the mold flash 164 is deposited on the exposed surface 145 of the sacrificial material 144.

FIG. 4 is a schematic side cross-sectional view of the section of the lead 122 and the casing 160 after removing the sacrificial material 144 and the mold flash 164. The sacrificial material 144 is removed from the recess 132 after forming the casing 160 so that the removal of the sacrificial material 144 breaks off the mold flash 164 on the exposed surface 145. In several applications, the sacrificial material 144 can be configured so that its strength is reduced during curing. In these embodiments, the sacrificial material 144 can be removed from the recess 132 by curing the material 144 and then washing the material 144 out of the recess 132. In other embodiments, the sacrificial material 144 can be removed from the recess 132 via other suitable methods. In either case, removal of the sacrificial material 144 and the mold flash 164 exposes a surface 133 of the pad 126 in the recess 132. After removing the sacrificial material 144 and the mold flash 164, the second surface 131a and the exposed surface 133 can be chemically treated and cleaned, and then a wettable material 156 can be deposited (e.g., plated) onto the second surface 131a and the exposed surface 133. In other embodiments, portions of the sacrificial material 144 may not be removed from the recess 132, and/or the wettable material 156 may not be deposited onto the second surface 131a and the exposed surface 133.

FIG. 5 is a schematic side cross-sectional view of the section of the lead 122 and the casing 160 after forming the interconnect element 150 on the pad 126. The illustrated interconnect element 150 includes a portion 152 disposed within the recess 132 and a second portion 154 projecting from the second surface 131a of the pad 126. The interconnect element 150 can be attached to the pad 126 by placing a flowable conductive material on the portion of the wettable material 156 adjacent to the second surface 131a and reflowing the conductive material so that a portion of the material flows into the recess 132.

One feature of the embodiment of the method illustrated above with reference to FIGS. 3-5 is that the mold flash 164 from the molding process is removed from the pad 126. An advantage of this feature is that the mold flash 164 is expected to not impair the structural and electrical connection between the interconnect elements 150 and the pads 126 of the microelectronic device 100. The improved structural and electrical connection between the interconnect elements 150 and the pads 126 increases the yield of the microelectronic devices 100. Another advantage of the illustrated method is that the mold flash 164 can be efficiently removed from the pad 126 without significantly damaging the casing 160, which also increases the yield of the microelectronic devices 100.

### D. Additional Embodiments of Pads on Leads

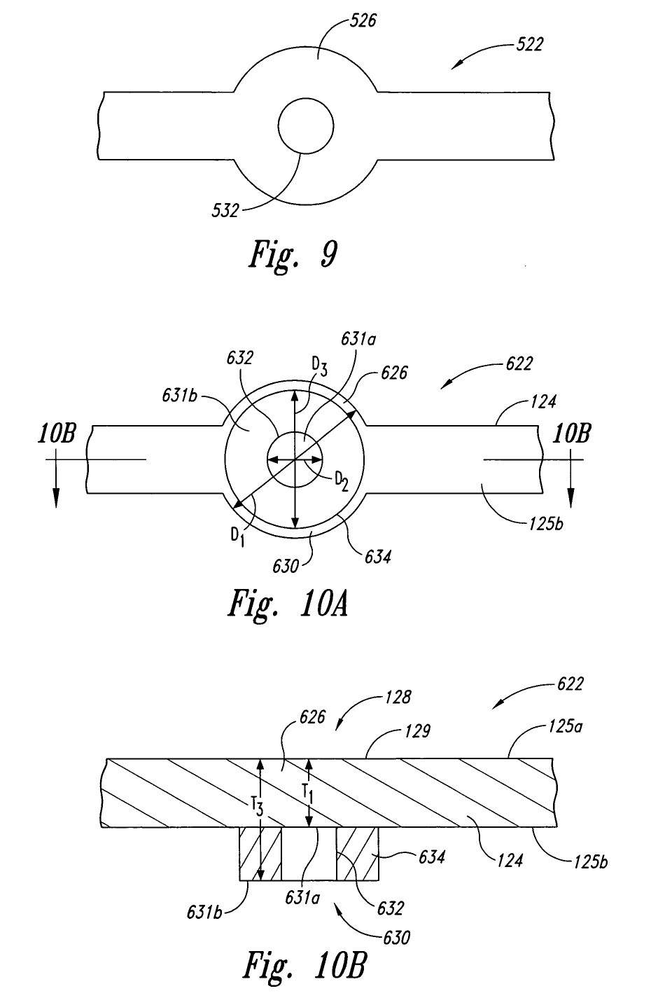

FIGS. 6-9 illustrate different configurations of recesses in pads of leads in accordance with other embodiments of the invention. For example, FIG. 6 is a top plan view of a section of a lead 222 having a pad 226 with a recess 232. The illustrated recess 232 is a blind groove with a triangular configuration that defines a triangular projection 234. FIG. 7 is a top plan view of a section of a lead 322 having a pad 326 with a recess 332. The illustrated recess 332 is a blind groove with a rectangular configuration that defines a rectangular projection 334. FIG. 8 is a top plan view of a section of a lead 422 having a pad 426 with a recess 432. The illustrated recess 432 is a blind groove with an “X”-shaped configuration that defines an “X”-shaped projection 434. FIG. 9 is a top plan view of a section of a lead 522 having a pad 526 with a recess 532. The illustrated recess 532 is a blind hole with a circular configuration. In additional embodiments, the pads can have recesses with different configurations.

FIG. 10A is a top plan view of a section of a lead 622 having a pad 626 in accordance with another embodiment of the invention. FIG. 10B is a schematic side cross-sectional view of the lead 622 taken substantially along the line 10B-10B in FIG. 10A. Referring to both FIGS. 10A and 10B, the illustrated pad 626 includes a first side 128 (FIG. 10B) positioned to face toward a die and a second side 630 opposite the first side 128. The first side 128 of the pad 626 has a first surface 129 (FIG. 10B) that can be generally coplanar with the first surface 125a (FIG. 10B) of the body 124. The second side 630 of the pad 626 includes a projection 634, a recess 632 in the projection 634, a second surface 631a in the recess 632 that can be generally coplanar with the second surface 125b of the body 124, and a third surface 631b on the projection 634. As such, the pad 626 has a first thickness T₁ (FIG. 10B) extending between the first surface 129 and the second surface 631a and a second, larger thickness T₃ (FIG. 10B) extending between the first surface 129 and the third surface 631b. The projection 634 can be constructed (e.g., plated) on a preformed lead or be formed as an integral portion of the lead. The illustrated projection 634 is an annular member with an inner diameter D₂ and an outer diameter D₃. The outer diameter D₃ can be less than or equal to the diameter D₁ of the pad 626. In either case, the illustrated recess 632 is sized to receive a portion of an interconnect element that is subsequently attached to the pad 626. In additional embodiments, the projection 634 may not include the recess 632 and/or may have a different configuration.

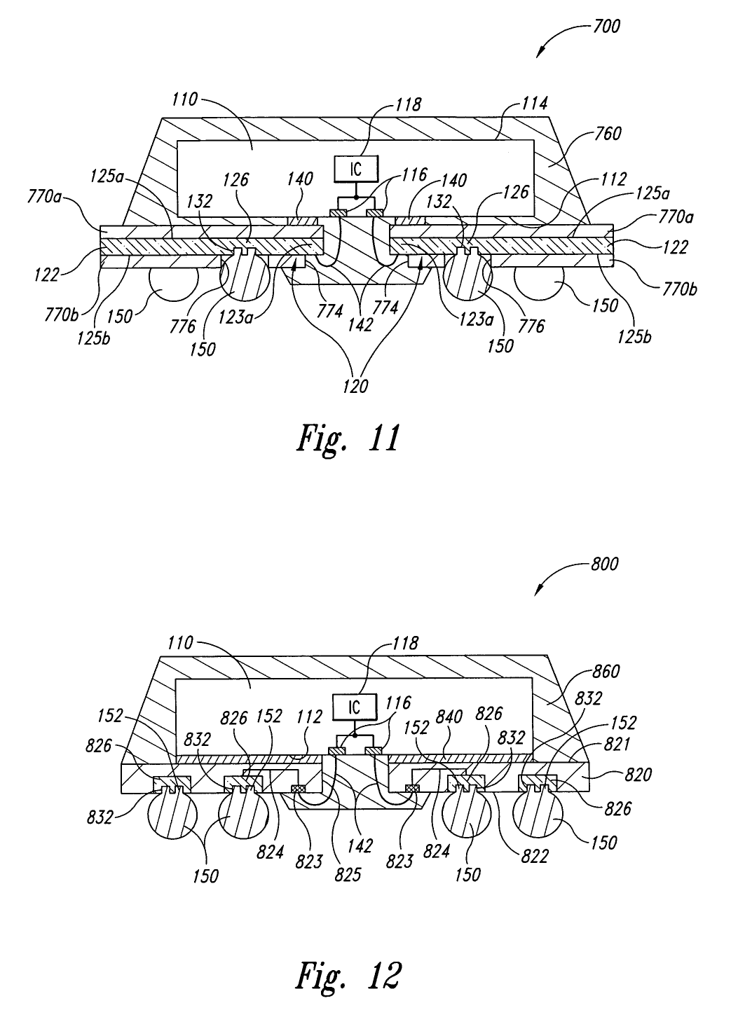

FIG. 11 is a schematic side cross-sectional view of a microelectronic device 700 in accordance with another embodiment of the invention. The microelectronic device 700 is generally similar to the microelectronic device 100 described above with reference to FIGS. 1-2B. For example, the microelectronic device 700 includes a die 110, a lead frame 120 attached to the die 110, a plurality of interconnect elements 150 attached to the lead frame 120, and a casing 760 encapsulating the die 110 and a portion of the lead frame 120. The illustrated microelectronic device 700, however, includes a first dielectric layer 770a on the first surface 125a of the leads 122 and a second dielectric layer 770b on the second surface 125b of the leads 122. The second dielectric layer 770b includes (a) a plurality of first openings 774 at the inner ends 123a of the leads 122 so that corresponding wire-bonds 142 can be attached to the leads 122, and (b) a plurality of second openings 776 at the pads 126 on the leads 122 so that corresponding interconnect elements 150 can be attached to the pads 126. The first and second dielectric layers 770a-b can be a solder mask or other suitable material for (a) inhibiting mold compound from flowing between the leads 122 and onto the pads 126, and (b) electrically insulating the leads 122 from external devices. In several embodiments, because the first and second dielectric layers 770a-b inhibit mold compound from flowing onto the pads 126, the microelectronic device 700 may be formed without placing a sacrificial material into the recesses 132 in the pads 126.

FIG. 12 is a schematic side cross-sectional view of a microelectronic device 800 in accordance with another embodiment of the invention. The microelectronic device 800 is generally similar to the microelectronic device 100 described above with reference to FIGS. 1-2B. For example, the microelectronic device 800 includes a microelectronic die 110, a support member 820 attached to the die 110, a plurality of interconnect elements 150 attached to the support member 820, and a casing 860 encapsulating the die 110 and a portion of the support member 820. The illustrated support member 820, however, is a dielectric interposer substrate having a first side 821 attached to the active side 112 of the die 110 with an adhesive 840, a second side 822 opposite the first side 821, a plurality of contacts 823 at the second side 822, a plurality of pads 826 at the second side 822, a plurality of conductive traces 824 electrically coupling the contacts 823 to corresponding pads 826, and a slot 825 extending between the first and second sides 821 and 822. The illustrated individual pads 826 include a recess 832 for receiving a portion 152 of a corresponding interconnect element 150.

From the foregoing, it will be appreciated that specific embodiments of the invention have been described herein for purposes of illustration, but that various modifications may be made without deviating from the spirit and scope of the invention. For example, many of the elements of one embodiment can be combined with other embodiments in addition to or in lieu of the elements of the other embodiments. Accordingly, the invention is not limited except as by the appended claims.

I/we claim:

1. A microelectronic device, comprising:
a microelectronic die including an integrated circuit and a plurality of terminals operably coupled to the integrated circuit; and
a plurality of conductive leads connected to the die and electrically coupled to corresponding terminals, the individual leads including a pad with a first side facing toward the die and a second side opposite the first side, the second side having at least one of a projection or a recess configured to interface with an interconnect element.

2. The microelectronic device of claim 1 wherein:
the second sides of the pads comprise the recesses;
the individual recesses comprise an annular groove extending from the second side to only an intermediate depth in the corresponding pad;
the microelectronic device further comprises a plurality of interconnect elements disposed on the second sides of corresponding pads, the individual interconnect elements including a portion received in the corresponding annular groove; and
the microelectronic device further comprises a casing covering the die and a portion of the conductive leads, the casing including a plurality of openings at corresponding pads.

3. The microelectronic device of claim 1 wherein:
the second sides of the pads comprise the recesses; and
the individual recesses comprise an annular groove.

4. The microelectronic device of claim 1 wherein:
the second sides of the pads comprise the recesses; and
the individual recesses comprise a blind hole.

5. The microelectronic device of claim 1 wherein:
the second sides of the pads comprise the recesses; and
the individual recesses extend from the second side to only an intermediate depth in the corresponding pad.

6. The microelectronic device of claim 1 wherein the individual pads further comprise a first portion with a first thickness and a second portion with a second thickness different than the first thickness.

7. The microelectronic device of claim 1 wherein:
the second sides of the pads comprise the recesses; and
the microelectronic device further comprises a sacrificial material disposed in at least some of the recesses.

8. The microelectronic device of claim 1 wherein:
the second sides of the pads comprise the recesses; and
the microelectronic device further comprises a plurality of interconnect elements disposed on the second sides of corresponding pads, the individual interconnect elements including a portion received in the corresponding recess.

9. The microelectronic device of claim 1 wherein the second sides of the pads comprise the projections.

10. The microelectronic device of claim 1 wherein:
the second sides of the pads comprise the projections; and
the individual projections comprise an annular member.

11. The microelectronic device of claim 1, further comprising a casing covering the die and a portion of the conductive leads, the casing including a plurality of openings at corresponding pads.

12. The microelectronic device of claim 1, further comprising:
a dielectric material covering a portion of the individual conductive leads; and
a casing covering the die and at least a portion of the dielectric material, the casing including a plurality of openings at corresponding pads.

13. The microelectronic device of claim 1, further comprising a solder mask covering a portion of the individual conductive leads.

14. A microelectronic device, comprising:
a microelectronic die including an integrated circuit and a plurality of terminals operably coupled to the integrated circuit; and
a support member attached to the die, the support member including a plurality of pads electrically connected to corresponding terminals on the die, the individual pads including a first surface facing toward the die and a second surface opposite the first surface, the second surface having a first portion spaced apart from the first surface by a first distance and a second portion spaced apart from the first surface by a second distance different than the first distance.

15. The microelectronic device of claim 14 wherein:
the support member comprises a dielectric substrate including a plurality of contacts electrically coupled to corresponding terminals on the die; and
the pads are electrically connected to corresponding contacts.

16. The microelectronic device of claim 14 wherein the support member comprises a lead frame including a plurality of leads with corresponding pads.

17. The microelectronic device of claim 14 wherein the individual pads further comprise a projection configured to interface with an interconnect element.

18. The microelectronic device of claim 14 wherein the individual pads further comprise a recess configured to interface with an interconnect element.

19. The microelectronic device of claim 14 wherein:
the individual pads further comprise a recess configured to interface with an interconnect element; and
the microelectronic device further comprises a sacrificial material disposed in the recesses.

20. The microelectronic device of claim 14 wherein:
the individual pads further comprise a recess at the second surface; and
the microelectronic device further comprises a plurality of interconnect elements disposed on corresponding pads, the individual interconnect elements including a portion received in the corresponding recess.

21. A lead frame for carrying a microelectronic die, the lead frame comprising a plurality of leads, the individual leads including a mounting surface for attachment to the die and a contact site for coupling to an interconnect element, the individual contact sites including a connection feature and a first surface generally parallel to the mounting surface, the connection feature having a second surface transverse to the mounting surface.

22. The lead frame of claim 21 wherein the individual connection features comprise at least one of a projection or a recess configured to interface with an interconnect element.

23. The lead frame of claim 21 wherein the connection features comprise recesses extending to only an intermediate depth in the corresponding pads.

24. The lead frame of claim 21 wherein:
the connection features comprise recesses; and
the lead frame further comprises a sacrificial material disposed in at least some of the recesses.

25. The lead frame of claim 21 wherein the connection features comprise projections.

26. The lead frame of claim 21, further comprising a dielectric material covering a portion of the individual leads, the dielectric material having a plurality of openings at corresponding contact sites.

27. A microelectronic device, comprising:
a microelectronic die including an integrated circuit and a plurality of terminals operably coupled to the integrated circuit;
a plurality of conductive leads attached to the die and electrically coupled to corresponding terminals, the individual leads including a pad; and
means for interfacing with corresponding interconnect elements at the pads.

28. The microelectronic device of claim 27 wherein the means for interfacing with corresponding interconnect elements at the pads comprise a plurality of recesses in corresponding pads.

29. The microelectronic device of claim 27 wherein:
the means for interfacing with corresponding interconnect elements at the pads comprise a plurality of recesses in corresponding pads; and
the individual recesses extend to only an intermediate depth in the pads.

30. The microelectronic device of claim 27 wherein the means for interfacing with corresponding interconnect elements at the pads comprise a plurality of projections at corresponding pads.

31. A method for manufacturing a microelectronic device, the method comprising:
mounting a microelectronic die to a support member having a plurality of pads;
electrically connecting a plurality of terminals on the die to corresponding pads on the support member;
encasing the die and a portion of the support member; and
removing a sacrificial material from recesses in corresponding pads after encasing the die.

32. The method of claim 31 wherein mounting the die to the support member comprises attaching the die to a lead frame having a plurality of leads, the leads having the corresponding pads.

33. The method of claim 31 wherein mounting the die to the support member comprises attaching the die to a dielectric substrate, the dielectric substrate having the pads.

34. The method of claim 31 wherein removing the sacrificial material from the recesses comprises curing the sacrificial material.

35. The method of claim 31, further comprising disposing the sacrificial material in the recesses before encasing the die and the portion of the support member.

36. The method of claim 31, further comprising removing material from the pads to form the recesses in the pads of the support member.

37. The method of claim 31, further comprising disposing a plurality of interconnect elements on corresponding pads after removing the sacrificial material, the individual interconnect elements including a portion received in the corresponding recess.

38. The method of claim 31 wherein removing the sacrificial material from the recesses comprises removing mold material disposed on the sacrificial material.

39. A method for manufacturing a microelectronic device, the method comprising:
mounting a microelectronic die to a lead frame having a plurality of leads, the individual leads including a pad with a first side facing toward the die and a second side opposite the first side, the second side having at least one of a projection or a recess positioned to interface with an interconnect element;
electrically coupling a plurality of terminals on the die to corresponding leads; and
encapsulating the die and a portion of the lead frame.

40. The method of claim 39 wherein mounting the die to the lead frame comprises attaching the die to a lead frame having a plurality of leads in which the individual leads include a pad with a recess extending to only an intermediate depth.

41. The method of claim 39 wherein mounting the die to the lead frame comprises attaching the die to a lead frame having a plurality of leads in which the individual leads include a pad with an annular groove.

42. The method of claim 39, further comprising removing mold material adjacent to the pads after encapsulating the die and the portion of the lead frame.

43. A method for manufacturing a lead frame, the method comprising:
providing a lead frame having a plurality of leads with pads configured to receive corresponding interconnect elements; and
removing material from the leads to form recesses at the pads.

44. The method of claim 43 wherein removing material from the leads comprises removing material from the leads to form a plurality of recesses extending to only an intermediate depth in the corresponding pads.

45. The method of claim 43 wherein removing material from the leads comprises removing material from the leads to form a plurality of annular grooves in corresponding pads.

46. The method of claim 43, further comprising depositing a sacrificial material into the recesses at the pads.
